(19) United States
(12) Patent Application Publication
(10) Pub. No.: US 2008/0247197 A1
(43) Pub. Date: Oct. 9, 2008

(54) ONE-WAY DIPOLAR COMPONENT WITH A PROTECTION AGAINST OVERCURRENT

(75) Inventors: Bertrand Rivet, Vouvray (FR); Frederic Gautier, Monnaie (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 12/098,293

(22) Filed: Apr. 4, 2008

(30) Foreign Application Priority Data
Apr. 5, 2007 (FR) 07/54288

(51) Int. Cl. H02M 1/14; H03K 17/74

(52) U.S. Cl. 363/44; 327/502

(57) ABSTRACT

A one-way dipolar component with overcurrent protection including, in parallel, a first one-way dipolar component with a positive temperature coefficient; and a second one-way dipolar component having the same biasing as the first one-way dipolar component having a conduction threshold voltage greater than the conduction threshold voltage at ambient temperature of the first one-way dipolar component, the second component comprising a silicon diode in series with a component of a zener diode type.

### BACKGROUND OF THE INVENTION

1. Field of the Invention

The present invention generally relates to the field of diodes and more specifically of diodes capable of operating at high frequency with the least possible losses on switching. “Diode” is here used to designate any one-way conduction dipolar component or component assembly.

2. Discussion of the Related Art

Some diodes such as silicon carbide SiC diodes or gallium nitride GaN diodes have the property of having particularly low switching losses, and especially, lower switching losses than conventional silicon diodes. SiC- or GaN-type diodes are thus a priori well adapted for high-frequency use.

However, SiC- or GaN-type diodes are much more expensive than silicon diodes. Their cost increases along with the surface area of these diodes, which surface area determines the maximum amount of direct current that the diode can conduct. There thus is a tendency to operate such diodes in the vicinity of the maximum current densities that they can stand.

FIG. 1 illustrates forward current-vs.-voltage characteristics of a silicon carbide diode supporting an average 8-ampere current, the junction temperature of this diode being 23° C. in the case of curve 3 and 150° C. in the case of curve 5. Below a given current, 2 amperes in the shown example, temperature coefficient α_{T} of the diode is negative, that is, for a given intensity, if the junction temperature of the diode increases, its forward voltage drop V_{F} decreases. However, temperature coefficient α_{T} becomes positive when the current flowing through the diode exceeds the above-mentioned 2-ampere threshold. Thus, at 23° C., when a given current is conducted by the diode, for example, 6 amperes, the diode initially has a forward voltage drop of approximately 1.55 V. The flowing of the current through the diode causes an increase in its junction temperature, which modifies its forward current-vs.-voltage characteristic and increases its forward voltage drop. This increase in the forward voltage drop causes an increase in the dissipated power and thus in the temperature, which modifies again the current-vs.-voltage characteristic. If the time for which a high current flows is long enough, a thermal runaway phenomenon creates; the diode heats more and more and this may causes its deterioration.

FIG. 2 shows a voltage step-up rectifying circuit. This circuit is powered by an A.C. voltage source 11 connected to a rectifying bridge 13. A coil 15 and a switch 17 which have a connection point 19 are arranged in series between the output terminals of the rectifying bridge. A diode 21 and a capacitor 23 are arranged, in series, in parallel with switch 17. The diode has its anode connected to coil 15, and the current which flows therethrough is called I_{F}. A load (not shown) may be placed across capacitor 23, and the output voltage is called Vₒᵤₜ.

Several steps can be distinguished in the operation of the circuit of FIG. 2. A first step comprises starting A.C. voltage source 11 while switch 17 is off. During this step, the rectified voltage charges capacitor 23 and coil 15 builds up power. Once the capacitor has been properly charged, the second step starts with the turning on of switch 17, after which said switch is controlled to turn off and on at a high frequency, which creates pulse overvoltages on node 19 and charges capacitor 23 to a raised voltage with respect to the value of the rectified voltage available at the output of rectifying bridge 13.

It is known that controlled switch 17 needs to operate at high frequency. Diode 21 needs to thus be able to switch fast and have the lowest possible switching losses. The use of a diode of SiC or GaN type as a diode 21 has thus been envisaged. However, experience proves that a diode of relatively large surface area, which is expensive, should be used.

### SUMMARY OF THE INVENTION

It is thus attempted to form a one-way dipolar component that can operate at high frequency and standing high currents, at least during transient periods.

To achieve all or part of these objects, as well as others, at least one embodiment of the present invention provides a one-way dipolar component with overcurrent protection comprising, in parallel, a first one-way dipolar component with a positive temperature coefficient; and a second one-way dipolar component having the same biasing as the first one-way dipolar component having a conduction threshold voltage greater than the conduction threshold voltage at ambient temperature of the first one-way dipolar component, the second component comprising a silicon diode in series with a component of a zener diode type.

According to an embodiment of the present invention, the component of the zener diode type comprises a bipolar transistor having its emitter connected to the silicon diode, and a reverse-connected zener diode having its anode connected to the base of the bipolar transistor and having its cathode connected to the collector of the bipolar transistor.

According to an embodiment of the present invention, the first one-way dipolar component is a diode made of a material from the group comprising silicon carbide and gallium nitride.

The present invention also provides a D.C. voltage supply incorporating a step-up rectifier comprising the above one-way dipolar circuit.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1, previously described, shows two current-vs.-voltage curves of a diode of SiC or GaN type formed at two different operation temperatures;

FIG. 2, previously described, shows a circuit in which a diode of SiC or GaN type can be used;

FIG. 3 shows voltage and intensity curves associated with the circuit of FIG. 2; and

FIGS. 4A, 4B, and 4C show different one-way dipolar components according to embodiments of the present invention.

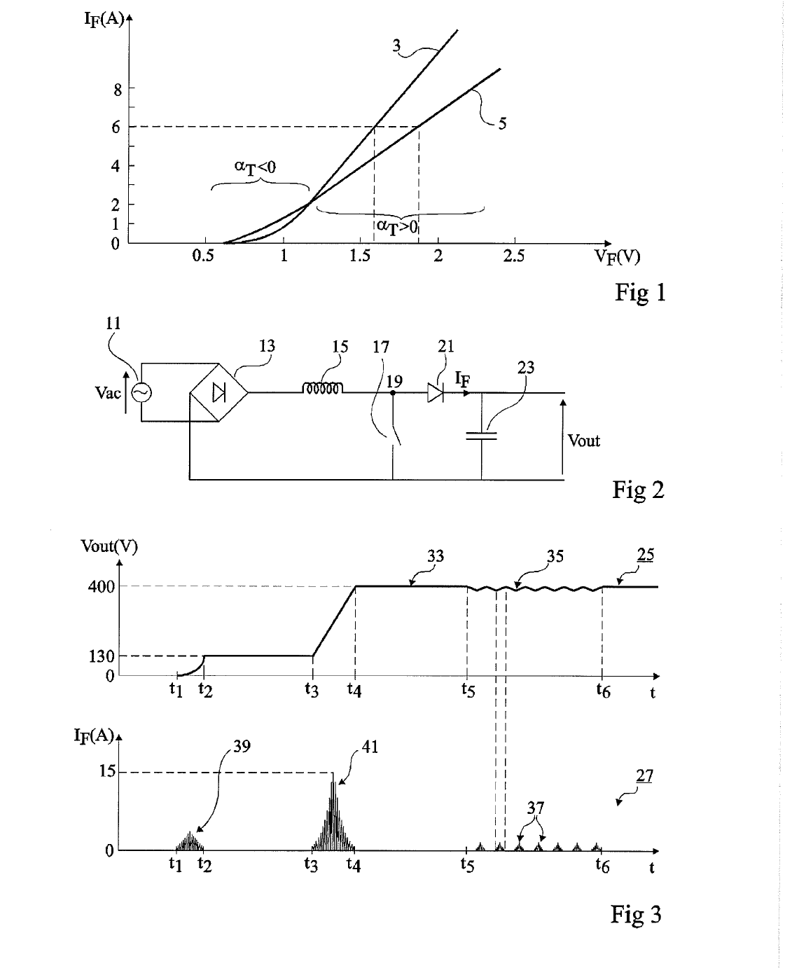

### DETAILED DESCRIPTION

FIG. 3 shows two curves illustrating the operation of the step-up rectifying circuit of FIG. 2. Curve 25 shows output voltage Vₒᵤₜ of the circuit along time, while curve 27 shows current I_{F} flowing through diode 21 along time. Both curves are drawn in the case where an A.C. voltage source 11 with a 90-V rms. Value is used.

As illustrated by curve 25, A.C. power supply 11 is started at a time t₁ while switch 17 is off. The output of rectifying bridge 13 charges capacitor 23, between time t₁ and a time t₂, via coil 15 and diode 21, which causes the rise of Vₒᵤₜ from 0 V to approximately 130 V (the peak value of the A.C. voltage). At a time t₃, switch 17 is controlled to be turned on and off at a high frequency so that the circuit operates in a known fashion as a voltage step-up device. Voltage Vₒᵤₜ then increases again between time t₃ and a time t₄. In the shown example, the circuit features (inductance of coil 15, off and on time periods of switch 17, and capacitance of capacitor 23) are selected so that voltage Vₒᵤₜ is approximately 400 V at time t₄. Once the 400 V are reached at the output, if no charge is applied to the circuit of FIG. 2, the output voltage remains substantially constant 33, and the circuit substantially does not consume power. When a load is connected at the circuit output, at a time t₅, capacitor 23 tends to discharge into it and power supply 11 recharges capacitor 23 to compensate for the power consumption of the load.

During supply periods, that is, each time the voltage provided by the rectifying bridge charges the capacitor and voltage Vₒᵤₜ increases, a current flows through diode 21. In steady state, that is, once capacitor 23 is charged to 400 V and discharges, then recharges 35 at high frequency to supply power to the load, an average nominal current 37 flows through diode 21, as illustrated on curve 27. During the first capacitor charge, between times t₁ and t₂, it can be acknowledged that average current 39 in diode 21 is on the same order of magnitude as the nominal current.

By the above analysis, the applicant has shown that, when an A.C. power supply 11 having a relatively low peak voltage is used, and when a voltage Vₒᵤₜ of much greater value than the peak voltage of the power supply is desired at the circuit output, a strong current surge appears between times t₃ and t₄ and a significant current I_{F} 41 flows through diode 21.

This type of operation poses no specific problem when diode 21 is a diode having a negative temperature coefficient, for example, a silicon diode.

Indeed, in this case, while the overcurrent occurs, the voltage across the diode drops. This voltage drop at least partially compensates for the current increase in the diode. Further, silicon diodes generally have a relatively low cost and it is not a significant disadvantage to slightly oversize the diode to take into account, if necessary, the increase in the power dissipated on starting.

However, if diodes of silicon carbide diode type or other diodes with a positive temperature coefficient are used, the high current in the diode during the starting period causes an increase in the voltage drop across the diode and risks causing a diode runaway and destruction effect. Further, as indicated previously, diodes of SiC diode type are generally expensive and it is desired to avoid increasing the surface area of such diodes. Means enabling to use a silicon carbide diode or the like having no more than the dimension capable of standing the nominal current in the diode are thus here provided, between times t₅ and t₆, as described previously in relation with FIG. 3.

According to an aspect of the present invention, it is desired to keep the advantages of fast switching of SiC-type diodes, while enabling use of diodes of small dimensions and to be able to at least withstand significant overcurrents.

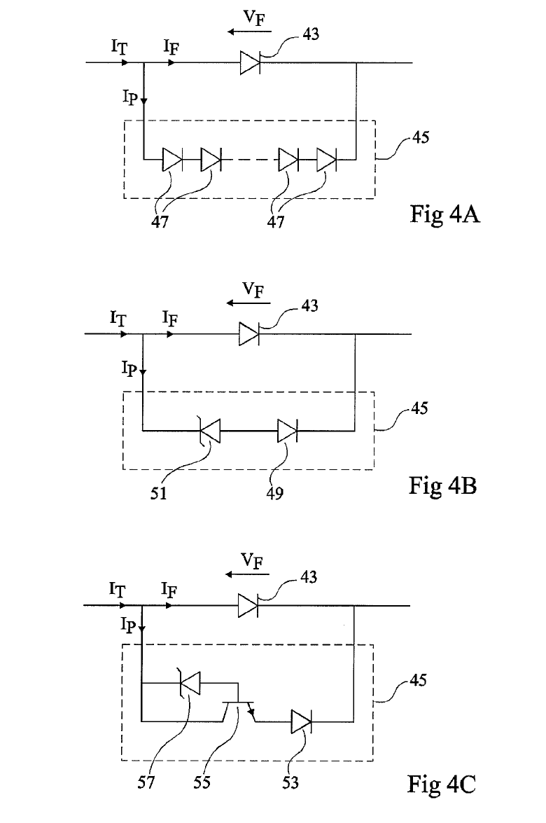

FIGS. 4A, 4B, and 4C illustrate various embodiments of a one-way dipolar component according to the present invention. This component comprises an SiC diode 43, in parallel with a one-way component 45 of same biasing. The intensity flowing through diode 43 is called I_{F}, the intensity flowing through component 45 is called I_{P}. The total current in the component is I_{T}, I_{T}=I_{F}+I_{P}.

One-way conduction component 45 is selected to have a conduction threshold voltage greater than that of diode 43. More specifically, component 45 is selected to turn on as soon as the voltage across diode 43 reaches a value corresponding to an allowed heating of this diode 43. Thus, in nominal operation, as long as the voltage drop across diode 43 remains close to its nominal value, one-way conduction device 45 does not turn on and the component as a whole substantially operates as if diode 43 were alone. However, as soon as the heating of diode 43 makes its forward voltage drop reach the threshold value of parallel component 45, this component takes over and conducts current. If, further, this component is selected to have a negative temperature coefficient, diode 43 will only turn back on when its temperature will have dropped enough for its forward voltage drop to correspond to the lowered voltage drop across component 45. Component 45 can thus be designated as a protection component.

In the embodiment of FIG. 4A, component 45 is formed of several diodes 47 in series. Diodes 47 for example are silicon diodes which generally have a relatively low cost, and at all events very low as compared with that of a silicon carbide diode, and which further have the advantage of having a negative temperature coefficient. As an example, to select the forward voltage drop at ambient temperature of protection device 45, the maximum temperature tolerated in the silicon carbide diode is determined for a nominal current, the current drop across this diode is determined for this maximum temperature, and the voltage drop is appropriately set in device 45. For example, if the maximum temperature tolerated in the silicon carbide diode corresponds to a 4.2-V voltage drop, seven silicon diodes 47 in series may be used as a protection device, each diode having, as known for silicon diodes, a voltage drop on the order of 0.6 V.

FIG. 4B illustrates an embodiment in which component 45 comprises the series connection of a silicon diode 49 and of a low-voltage zener power diode 51, diode 49 being assembled according to the same biasing as diode 43.

FIG. 4C illustrates a third embodiment of the present invention in which component 45 is formed of the series connection of the collector-emitter circuit of a transistor 55 and of a diode 53 biased in the same direction as diode 43. The base of transistor 55 is connected to its collector via a low-voltage zener diode 57 thermally coupled to transistor 55 to take advantage of the negative temperature coefficient of the zener diode and thus allow an adaptation to the thermal conditions.

It should be noted by those skilled in the art that the various embodiments of the present invention have their specific advantages. For example, the first embodiment can only be advantageously used when the threshold voltage for which parallel device 45 is desired to turn on corresponds to the forward voltage drop of an integral number of diodes. A finer setting can be obtained when all the components of element 45 have a voltage drop with a negative temperature coefficient on flowing of a current I_{P}. The embodiments of FIGS. 4A and 4C have this advantage.

Further, it should be noted by those skilled in the art that the various embodiments based on silicon components provided to form component 45 are, generally, much less expensive than a silicon carbide type diode.

According to an advantage of the embodiments of the present invention, protection device 45 only starts operating in very specific cases where diode 43 heats up beyond a threshold. In many assemblies such as that illustrated in FIG. 2, such high overintensity periods are very short as compared with the total operating time of a system. For example, in the case of a step-up rectifier such as shown in FIG. 2, the overcurrent only substantially appears at the system starting, that is, for a few milliseconds, after which the system can operate with no power consumption or at reduced nominal power consumption for very long time periods, of several hours, or even of several days. Further, during nominal power consumption periods, the advantage of very low losses in the SiC-type diode is kept.

Various alterations, modifications, and improvements will occur to those skilled in the art. In particular, diode 43 has been described as being a silicon carbide SiC diode. As a variation, this diode may be any type of fast diode having a positive temperature coefficient, for example, a gallium nitride GaN diode.

Further, one-way dipolar component 43 has been described as being a diode. As a variation, this one-way dipolar component 43 may be any type of one-way component or one-way component association having a positive total temperature coefficient.

Moreover, although three specific embodiments of the branching/protection device according to the present invention have been described, other equivalent structures will occur to those skilled in the art.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed:

1. A one-way dipolar component with overcurrent protection, comprising, in parallel:
a first one-way dipolar component with a positive temperature coefficient; and
a second one-way dipolar component having the same biasing as the first one-way dipolar component having a conduction threshold voltage greater than the conduction threshold voltage at ambient temperature of the first one-way dipolar component, the second component comprising a silicon diode in series with a component of a zener diode type.

2. The dipolar component of claim 1, wherein the component of the zener diode type comprises a bipolar transistor having its emitter connected to the silicon diode, and a reverse-connected zener diode having its anode connected to the base of the bipolar transistor and having its cathode connected to the collector of the bipolar transistor.

3. The dipolar component of claim 1, wherein the first one-way dipolar component is a diode made of a material from the group comprising silicon carbide and gallium nitride.

4. A D.C. voltage supply incorporating a step-up rectifier comprising the one-way dipolar circuit of claim 1.
